(19) United States
(12) Patent Application Publication
(10) Pub. No.: US 2006/0145288 A1
(43) Pub. Date: Jul. 6, 2006

(54) Method of forming shallow trench isolation of semiconductor device

(75) Inventor: Han Seok Ko, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/322,865

(22) Filed: Dec. 29, 2005

(30) Foreign Application Priority Data
Dec. 31, 2004 (KR) 10-2004-0117849

(51) Int. Cl. H01L 29/00; H01L 21/76

(52) U.S. Cl. 257/510; 438/424; 438/429

(57) ABSTRACT

A method of forming a shallow trench isolation (STI) of a semiconductor device is disclosed. The method includes the steps of (a) serially forming a pad oxide layer and a pad nitride layer on a silicon substrate, and serially etching the pad nitride layer, the pad oxide layer, and the silicon substrate to form a first trench on the silicon substrate, (b) selectively forming an epitaxial silicon layer on a silicon surface in the first trench to form a second trench, and (c) filling inner walls of the second trench with a Chemical Vapor Deposition (CVD) oxide. Herein, a size of the second trench may be smaller than a size of the first trench. Thus, a trench may have a size smaller than the size of a corresponding photoresist layer pattern, thereby facilitating formation of an STI structure having a relatively fine line width.

This application claims the benefit of Korean Patent Application No. P2004-117849, filed on Dec. 31, 2004, which is hereby incorporated by reference as if fully set forth herein.

### BACKGROUND OF THE INVENTION

1. Field of the Invention

The present invention relates to a semiconductor device, and more particularly, to a method of forming a shallow trench device isolation (STI) of a semiconductor device.

2. Discussion of the Related Art

In order to obtain high integration of a semiconductor apparatus, various semiconductor devices, such as transistors, capacitors, and various lines (or wires), that configure the semiconductor apparatus should be formed on an extremely narrow area. Therefore, since the distance between each element is short, the isolation between each element should be enhanced. In the related art, a LOCOS type field oxide layer has been widely used in order to electrically isolate the semiconductor devices that configure the semiconductor apparatus. Herein, the LOCOS type field oxide layer is formed by (partially) oxidizing a silicon substrate.

However, due to a bird's beak effect that may occur during the process of forming the LOCOS type oxide layer, part of the LOCOS type oxide layer may penetrate an active layer of the substrate in which the semiconductor devices are formed, thereby interrupting or reducing the high integration of the semiconductor apparatus. Therefore, a field oxide layer that has a small surface and an excellent isolation characteristic at the same time is desired. A general example of such field oxide layer is a trench type field oxide layer. And, most particularly, a shallow trench isolation (hereinafter, referred to as “STI”) is the most extensively used.

The related art method for forming a shallow trench isolation (STI) will be described in detail with reference to FIG. 1.

A pad oxide layer 22 and a pad nitride layer 24 are serially formed on a silicon substrate 10. Then, a photoresist material is coated on the pad nitride layer 24. Thereafter, by performing a photolithography process, a photoresist layer pattern (not shown), which defines an active area and a field area of the substrate 10, is formed.

The photoresist layer pattern is used as an etch mask, and then the pad nitride layer 24 and the pad oxide layer 22 are serially etched. Simultaneously or subsequently, an inside of the substrate 10 is etched to a predetermined depth using another etch process, thereby forming a trench 20. After forming the trench 20, the photoresist layer pattern is removed (e.g., by a washing and/or ashing process).

Subsequently, by using a thermal oxidation process, a thin layer of STI liner oxide is formed inside the trench 20, thereby modifying the silicon surface. Then, the trench 20 is filled with an STI oxide, such as a Chemical Vapor Deposition (CVD) oxide or a high density plasma CVD oxide using an 0₃-TEOS oxide film.

The STI oxide is deposited on an entire surface of the pad nitride layer 24. However, after filling the trench 20, the surface of the STI oxide layer may not be uniform due to a curvature on a lower portion thereof. Therefore, the entire surface of the STI oxide 30 is polished (or planarized) by using a Chemical Mechanical Polishing (SMP) process.

Finally, the pad oxide layer 22 and the pad nitride layer 24 formed on the substrate 10 are both removed by using a wet-etching process, thereby completing the STI, which will be used as a device isolation layer.

The STI formed by the above-described method is formed in compact sizes as the semiconductor devices become more highly integrated. However, when using an STI having a critical dimension (CD) of 0.25 μm or less, it is difficult to fill the inside of the trench 20 reliably with the STI oxide. More specifically, the oxide material cannot fully fill the inside of the trench 20, which may have a narrow width, because its opening 20a may be too narrow. When the opening of the trench 20 is too narrow for all variations in the CVD oxide deposition process, the CVD oxide may be mainly deposited on corner regions of the trench 20, which may increase the risk of forming a void inside the trench 20. Furthermore, due to the limitations of the photolithography process, if the CD is too small (or low), there may be difficulties in reducing the width of the photoresist layer pattern to less than a predetermined size, the photoresist layer pattern being used to form the trench 20.

### SUMMARY OF THE INVENTION

Accordingly, the present invention is directed to a method of forming a shallow trench isolation of a semiconductor device that substantially obviates one or more problems due to limitations and disadvantages of the related art.

An object of the present invention is to provide a method of forming a shallow trench isolation of a semiconductor device that can overcome limitations and/or risks of the photolithography process and densely fill the inside of a trench with an STI oxide by adjusting (e.g., decreasing) a line width of an STI using (e.g., by forming or growing) an epitaxial silicon layer in the trench.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of forming a shallow trench isolation (STI) structure may include the steps of (a) serially forming a pad oxide layer and a pad nitride layer on a silicon substrate, and serially etching the pad nitride layer, the pad oxide layer, and the silicon substrate to form a first trench in the silicon substrate, (b) selectively forming an epitaxial silicon layer on a silicon surface in the first trench to form a second trench, and (c) filling inner walls of the second trench with a Chemical Vapor Deposition (CVD) oxide. Herein, a size (e.g., width) of the second trench may be smaller than a size (e.g., width) of the first trench. Thus, a trench may be formed to have a size smaller than the size (e.g., a width or critical dimension [CD]) of a photoresist layer pattern formed by a photolithography process, thereby facilitating the formation of an STI structure having a fine line width.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a trench of an STI formed by using a related art method;

FIG. 2 illustrates an epitaxial silicon layer selectively formed on inner walls of a trench (defined primarily by a patterned photoresist layer) using a method according to the present invention; and

FIG. 3 illustrates a cross-section of a filled STI structure according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

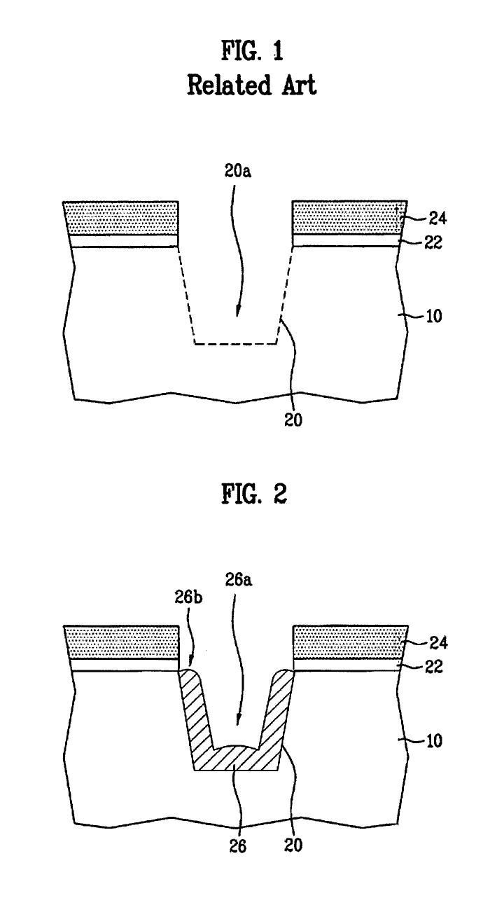

Hereinafter, the method of forming an STI of a semiconductor device will now be described in detail with reference to FIG. 2.

Referring to FIG. 2, a pad oxide layer 22 and a pad nitride layer 24 are serially formed on a silicon substrate 10. Silicon-containing substrates other than single-crystal silicon (e.g., silicon-germanium mixtures or alloys, epitaxial silicon and/or germanium layers, etc.) are also suitable. Also, materials other than silicon nitride that may form a hard mask may be suitable as layer 24. Then, a photoresist material is coated on the pad nitride layer 24, which is subjected to a photolithography process, so as to form a photoresist layer pattern (not shown). The photoresist layer pattern defines a minimum (or initial) active area and a maximum (or initial) field area of the substrate 10.

Subsequently, the pad nitride layer 24 and the pad oxide layer 22 are etched, thereby forming a trench 20 in the substrate 10. The above-described method of forming the trench 20 is essentially identical to that described in FIG. 1. The difference between the method according to the present invention and the related art method is that the trench 20 according to the present invention may have a size larger than the trench size defined by the applicable design rules. Alternatively, STI structures having a width smaller than the critical dimension (e.g., as defined by applicable design rules) may be formed according to the present invention.

Subsequently, silicon (or other suitable silicon-containing material, such as germanium or a silicon-germanium mixture) may be grown by epitaxy within the trench 20, so as to form a silicon epitaxy layer 26. At this point, the formation of an epitaxial silicon layer in the trench generally results in an increase in the active area size and a decrease in the field area size. Thus, the size of the final active area is greater than the size of the initial active area, and the size of the final field area is smaller than the size of the initial field area. Also, the pad oxide layer 22 and the pad nitride layer 24 are on the silicon surface of the substrate 10, except the inner walls of the trench 20. Therefore, the silicon epitaxy layer 26 may be selectively formed on the inner walls of the trench 20. By forming the silicon epitaxy layer 26, the damage caused by the etching process on the silicon substrate of the inner walls of the trench 20 may be removed. Also, as is shown in FIG. 2, an epitaxial silicon layer generally provides the trench region to be filled with insulator with somewhat rounded corners, which can be advantageous for reducing (1) adverse effects of local electrical fields that may be concentrated at the active area corners and (2) stress forces that may be imparted on subsequently formed insulator materials.

Further, as discussed above, an STI having a size smaller than the field area defined by the photoresist layer pattern may be formed. In other words, by controlling the growth and/or thickness of the epitaxial silicon layer 26, the limitations and/or risks resulting from the error margins of the photolithography process can be overcome, thereby forming a trench opening 26a (shown in FIG. 2) smaller than the opening 20a (shown in FIG. 1) of the trench formed by the photoresist layer pattern.

In addition, when forming the silicon epitaxy layer 26 on the inner walls of the trench 20, the epitaxial silicon layer 26 may have the structure shown in FIG. 2. Therefore, a step difference may occur between the upper portion of the trench 20 and the pad oxide and pad nitride layers 22 and 24. Accordingly, the step difference area 26b pushes the portions of the pad nitride layer 24 and the pad oxide layer 22, which are relatively close to the trench opening 26a, laterally to the opposite direction, away from the remaining trench opening. More specifically, this can enlarge the trench opening 26a so that the STI oxide can fill the trench 20 with more efficiency during the STI oxide filling process that will follow.

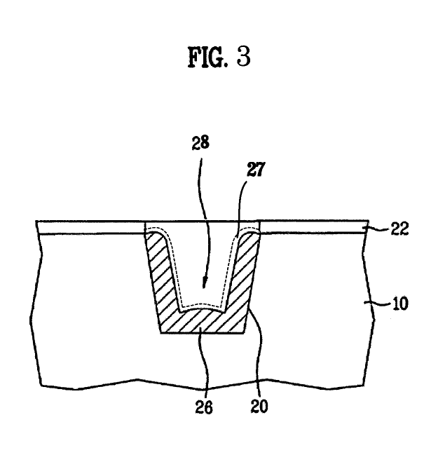

Subsequently, and as shown in FIG. 3, the inside of the trench having the silicon epitaxy layer 26 formed thereon is filled with an STI oxide 28. At this point, in order to modify the surface of the silicon epitaxy layer 26, it is preferable to form an STI liner oxide layer 27 by or using a thermal oxidation process. After filling the trench with the STI oxide 28, the surface of the STI oxide layer is polished (or planarized) by a Chemical Mechanical Polishing (CMP) process. Thereafter, the pad nitride layer 24 is removed by a wet-etching process (e.g., using aqueous phosphoric acid), thereby completing an STI structure having a relatively fine line width.

The above-described method of forming an STI of a semiconductor device according to the present invention has the following advantages.

By forming a trench having a size smaller than the size of the photoresist layer pattern, the STI may have a more compact size. In addition, forming an epitaxial silicon layer may compensate for damage that may be caused by the etching process on the silicon surface of the inner walls of the trench. Furthermore, by forming the silicon epitaxy layer, the pad nitride layer and the pad oxide layer may be relatively removed or distant from the trench, thereby enlarging the trench opening, which facilitates filling the trench with STI oxide. Therefore, void formation that may be caused by overhanging CVD oxide material as it is deposited on the upper corner regions of the trench can be reduced or prevented.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of forming a shallow trench isolation (STI) of a semiconductor device, the method comprising the steps of:
(a) serially forming a pad oxide layer and a pad nitride layer on a silicon substrate, and serially etching the pad nitride layer, the pad oxide layer, and the silicon substrate to form a first trench in the silicon substrate;
(b) selectively forming an epitaxial silicon layer on a silicon surface in the first trench to form a second trench; and
(c) filling inner walls of the second trench with a Chemical Vapor Deposition (CVD) oxide.

2. The method according to claim 1, wherein a size of the second trench is smaller than a size of the first trench.

3. The method according to claim 1, further comprising a step of thermally oxidizing the inner walls of the second trench to form an STI lining oxide layer, prior to step (c).

4. A semiconductor device comprising a shallow trench isolation (STI) formed by the method according to claim 1.

5. A method of forming a shallow trench isolation (STI) structure, comprising the steps of:
(a) growing a silicon-containing epitaxial layer in a plurality of trenches in a silicon-containing substrate; and
(b) filling a remainder of each trench with an insulator.

6. The method according to claim 5, further comprising, prior to step (a), depositing a mask layer and a pad oxide layer on the silicon-containing substrate.

7. The method according to claim 6, further comprising, after depositing the mask layer and pad oxide layer, patterning at least the mask layer to define a pre-trench region in the substrate.

8. The method according to claim 7, further comprising, after patterning at least the mask layer, etching the mask layer, pad oxide layer, and substrate to form the trench.

9. The method according to claim 8, wherein the mask layer comprises silicon nitride.

10. The method according to claim 5, wherein the insulator comprises a silicon oxide.

11. The method according to claim 5, wherein filling the remainder of each trench comprises Chemical Vapor Depositing (CVD) the insulator.

12. The method according to claim 11, wherein the insulator comprises a silicon oxide.

13. The method according to claim 5, further comprising a step of thermally oxidizing the inner walls of the second trench to form an STI lining oxide layer, prior to step (b).

14. A shallow trench isolation (STI) structure, comprising:
(a) a silicon-containing substrate,
(b) a trench in the silicon-containing substrate;
(c) an epitaxial silicon layer on a surface in the trench; and
(d) a silicon oxide-containing insulator filling the trench.

15. The structure according to claim 13, further comprising a thermal oxide liner between the epitaxial silicon layer and the silicon oxide-containing insulator.

16. The structure according to claim 13, further comprising forming a pad oxide layer on the silicon-containing substrate, and a pad nitride layer on the pad oxide layer.

17. The structure according to claim 14, wherein the silicon-containing substrate comprises a single crystal silicon substrate and/or an epitaxial silicon layer.

18. The structure according to claim 14, wherein the silicon oxide-containing insulator comprises a Chemical Vapor Deposition (CVD) silicon oxide.
